(19) United States
(12) Patent Application Publication
(10) Pub. No.: US 2005/0150462 A1
(43) Pub. Date: Jul. 14, 2005

(54) Lift pin for used in semiconductor manufacturing facilities and method of manufacturing the same

(75) Inventors: Jung-Hun Seo, Gyeonggi-do (KR); Yun-Ho Choi, Gyeonggi-do (KR); Young-Wook Park, Gyeonggi-do (KR); Jeong-Tae Kim, Gyeonggi-do (KR)

Correspondence Address: MARGER JOHNSON & MCCOLLOM, P.C., 1030 SW MORRISON STREET, PORTLAND, OR, 97205, US

(73) Assignee: Samsung Electronics Co., Ltd., Suwon-Si (KR)

(21) Appl. No.: 11/030,808

(22) Filed: Jan. 5, 2005

(30) Foreign Application Priority Data
Jan. 5, 2004 (KR) 2004-0233

(51) Int. Cl. C23C 16/00

(52) U.S. Cl. 118/728; 29/592

(57) ABSTRACT

Provided are a lift pin capable of preventing aluminum from depositing on the lift pin when depositing a metallic layer on a wafer through chemical vapor deposition. a system using the lift pin, and a method of manufacturing the same. The lift pin is made of stainless steel and is oxidized at a predetermined temperature for a predetermined time, such that the lift pin is not deposited with aluminum during a CVD process. Since the CVD vacuum processing chamber utilizes the heater and the lift pin which are made of oxidized SUS material, aluminum does not deposit on the heater and the lift. Therefore, when the lift pin is lowered, the lift pin is not lowered by its own weight, thereby preventing a wafer from being broken. Also, the lift pin is prevented from being ruptured by a robot moving in and out of an opening of the CVD vacuum processing chamber.

### CROSS-REFERENCE TO RELATED APPLICATION

This application claims the benefit of Korean Patent Application No. 2004-233, filed on Jan. 5, 2004, the disclosure of which is hereby incorporated herein by reference in its entirety.

### BACKGROUND OF THE INVENTION

1. Technical Field

The present invention relates to a lift pin used in semiconductor manufacturing facilities and, more particularly, to a lift pin capable of preventing aluminum from depositing on the lift pin when depositing a metallic layer on a wafer through chemical vapor deposition and a method of manufacturing the same.

2. Discussion of the Related Art

In general, in the course of manufacturing semiconductor devices, a wafer is passed through several processes, such as a depositing process, an etching process, a cleaning process, a drying process and the like. Processes of forming a material layer and patterning the material layer are carried out through physical/chemical deposition to produce the semiconductor device.

Apparatuses for forming a material layer generally utilize a chemical vapor deposition (CVD) system, by which a vapor compound is resolved to form a thin film on a semiconductor substrate using a chemical reaction.

Typical examples of the CVD system are disclosed in U.S. Pat. Nos. 5,262,029 and 5,838,529. A silicon wafer is positioned on a substrate holder by an electrostatic chuck, while a CVD process is implemented in a vacuum processing chamber. A process gas is supplied into the vacuum processing chamber through various devices, such as a gas nozzle, gas ring, gas dispersing plate or the like. The system includes a transfer mechanism, a gas supply system, a liner, a lift mechanism, a robot arm, a fastener, a rod lock, a door mechanism and the like.

FIG. 1 is a schematic view of a conventional CVD system.

The CVD system includes a vacuum processing chamber 10 having an opening 11 closing the vacuum processing chamber in a vacuum state, in which a CVD process is carried out, and a pedestal 20 for lifting a wafer W, which is transferred by a wafer transfer robot (not shown) and loaded in the vacuum processing chamber through the opening 11, to a following process.

The pedestal 20 includes an edge ring 21 on an upper surface of the pedestal 20 for preventing a certain material from being deposited on the upper surface of the pedestal 20 and a lower portion of the vacuum processing chamber 10 when carrying out the CVD process, a plurality of lift pins 22 slidably coupled to an upper portion of the pedestal 20, and a lift ring 23 vertically movably coupled to a lower portion of the pedestal 20 for supporting lower ends of the lift pins 22 and lifting the lift pins 22 above the upper surface of the pedestal 20.

The plurality of lift pins 22 lift the wafer W, which is inserted into the opening 11 by the wafer transfer robot. Then the lifted wafer W is disposed in the edge ring 21 by lifting the pedestal 20.

The pedestal 20 includes a gas supply plate 30 and a heater 40 on the upper portion of the pedestal 20. The gas supply plate 30 has at a center thereof a gas inlet 31 for supplying a reaction gas into the vacuum processing chamber 10, and at a lower portion thereof a showerhead 32 of a gas distribution plate formed with a plurality of holes or passages 32a. The reaction gas flowing through the gas inlet 31 is injected in the vacuum processing chamber 10 by the showerhead 32.

The heater 40 is supplied with a power under control of a controller (not shown) to heat the pedestal 20 and the wafer W.

The lift pins 22 are made of ceramic for a wafer of 200 mm and are made of SUS material for a wafer of 300 mm.

When the cumulative number of formed wafers exceeds 400 sheets, about a ⅔ portion of the lift pin 22 is deposited with aluminum during the CVD process, as shown by a white color in FIG. 2. When the cumulative number of the formed wafers exceeds 1000 sheets the entire lift pin 22 is completely deposited with aluminum during the CVD process, as shown by a white color in FIG. 3.

In the CVD system, when the lift ring 23 is lifted and then lowered, a plurality of lift pins 22 should be lowered by their weight. However, when the lift pins are deposited with aluminum, the wafer may be broken. There is another problem in that the lift pins 22 can be ruptured by the robot moving in and out the opening 11.

### SUMMARY OF THE INVENTION

A lift pin for use in a semiconductor manufacturing CVD process, a method manufacturing the lift pin for use in the CVD process, and a CVD processing system utilizing a plurality of lift pins are provided where the lift pin is made from oxidized stainless steel so that aluminum from reaction gases used in the CVD process is not deposited on the lift pin during the CVD process.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a schematic view of a conventional CVD system;

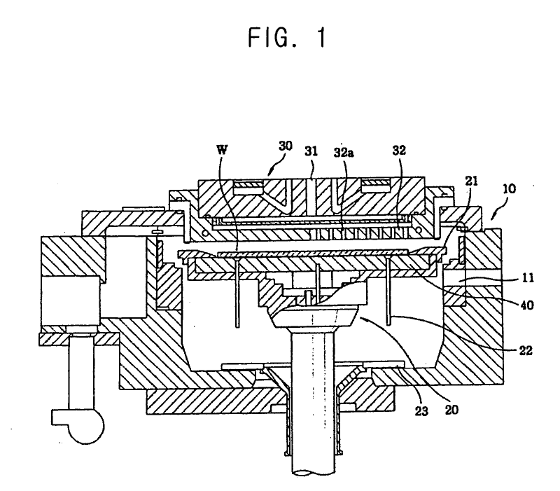

FIG. 2 is a photograph depicting a state where conventional lift pins are deposited with aluminum when 400 sheets of wafers are formed through a CVD process;

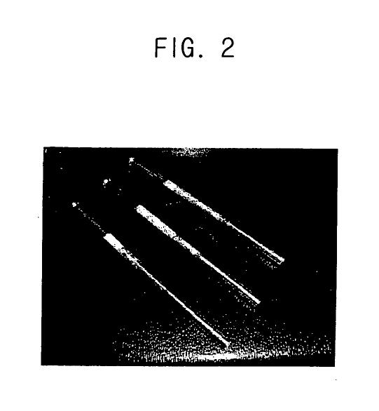

FIG. 3 is a photograph depicting a state where a conventional lift pin is deposited with aluminum when 1000 sheets of wafers are formed through a CVD process;

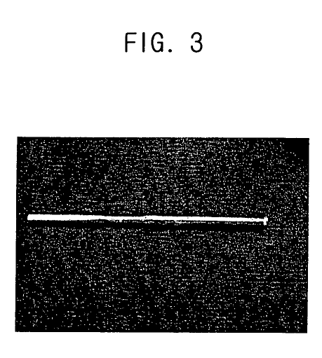

FIG. 4 is a schematic view of a CVD system according to an embodiment of the present invention; and

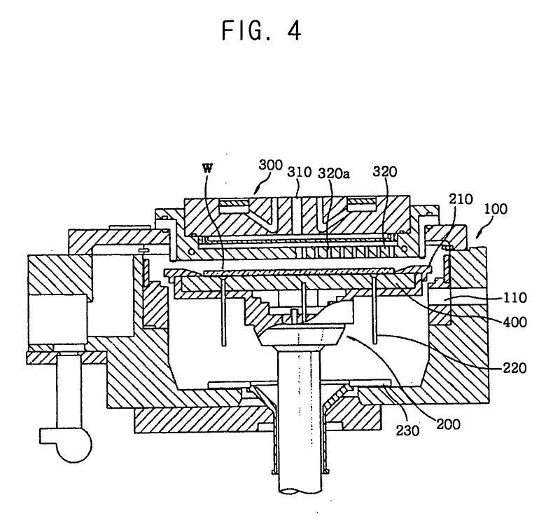

FIG. 5 is a photograph depicting a state where a lift pin of an embodiment of the present invention is not deposited with aluminum after 2000 sheets of wafers have been treated in a CVD process.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, this embodiment is provided so that this disclosure will be thorough and complete, and will fully convey the scope of the invention to those skilled in the art. In the drawings, the thickness of layers and regions are exaggerated for clarity. Like numbers refer to like elements throughout the specification.

A CVD system of an embodiment of the present invention includes a vacuum processing chamber 100 having an opening 110 closing the vacuum processing chamber in a vacuum state, in which a CVD process is carried out, and a pedestal 200 for lifting a wafer W, which is transferred by a wafer transfer robot (not shown) and is loaded in the vacuum processing chamber through the opening 110, for a subsequent process.

The pedestal 200 includes an edge ring 210 on an upper surface of the pedestal 200 for preventing material from being deposited on the upper surface of the pedestal 200 and the lower portion of the vacuum processing chamber 100 when carrying out the CVD process. The pedestal 200 includes a plurality of lift pins 220 slidably coupled to an upper portion of the pedestal 200, and a lift ring 230 vertically movably coupled to a lower portion of the pedestal 200 for supporting lower ends of the lift pins 220 and lifting the lift pins 220 above the upper surface of the pedestal 200. The lift ring 230 is contained in a lift hoop.

The plurality of lift pins 220 lift the wafer W, which is inserted into the opening 110 by the wafer transfer robot, and the lifted wafer W is disposed in the edge ring 210 by lifting the pedestal 200.

The pedestal 200 includes a gas supply plate 300 and a heater 400 on the upper portion of the pedestal 200. The gas supply plate 300 has at a center portion a gas inlet 310 for supplying a reaction gas into the vacuum processing chamber 100, and has at a lower portion a showerhead 320 of a gas distribution plate formed with a plurality of holes or passages 320a. The reaction gas flowing through the gas inlet 310 is injected in the vacuum processing chamber 100 by the showerhead 320.

The heater 400 is supplied with a power under a control of a controller (not shown) to heat the pedestal 200 and the wafer W.

An aluminum source comprises methylpyrrolidine alane (MPA) precursor, dimethylethylethylamaine alane (DMEAA) precursor, dimethylaluminum hydridge (DMAH) or trimethylamine alane (TMAA) precursor. Free electrons of the aluminum source function as a catalyst of a source and decompose in an underfilm having many free electrons, so that the aluminum is easily deposited on the lift pins 220 or the heater 400.

In order to prevent the aluminum from being deposited on the lift pins 220 or the heater 400, a material of very high specific resistance has to be used as the aluminum source. The lift pins 220 and the heater 400 are made of SUS material. Surfaces of the lift pins and the heater are heat treated in a hot oven of about 400° C. for 4 to 36 hours, so that the surfaces are oxidized. When the SUS material of the lift pin 220 and the heater 400 is oxidized, the hot oven is maintained in an air, nitrogen or inert gas atmosphere, or a vacuum state. For the vacuum state, the heat treatment is implemented at a pressure above 5×10⁻³ Torr.

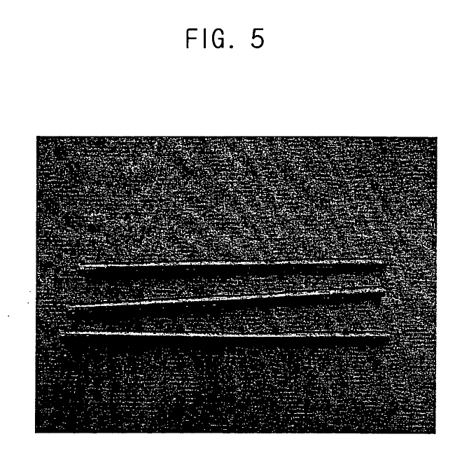

When the cumulative number of the formed wafers exceeds 2000 sheets, the lift pins 220 are not deposited with aluminum, as shown in FIG. 5.

With the above description, since the vacuum processing chamber utilizes the heater and the lift pin which are made of oxidized SUS material, the heater and the lift pin are not deposited with aluminum. Therefore, when the lift pin is lowered, the lift pin is not lowered by its own weight, thereby preventing a wafer from being broken. Also, it can prevent the lift pin from being ruptured by a robot moving in and out of the opening of the vacuum processing chamber.

In addition, since the lift pin is not deposited with aluminum, it can prolong the period of process management, thereby improving productivity of semiconductor devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A lift pin for use in semiconductor manufacturing CVD processing, comprising stainless steel oxidized at a predetermined temperature for a predetermined time adapted to prevent aluminum from a reaction gas from depositing on the lift pin during a CVD process.

2. The lift pin of claim 1, wherein the predetermined temperature is about 400° C., and the predetermined time comprises a range of about 4 to 36 hours.

3. The lift pin of claim 2, wherein the reaction gas is chosen from methylpyrrolidine alane (MPA) precursor, dimethylethylethylamaine alane (DMEEAA) precursor, dimethylaluminum hydridge (DMAH) precursor, and trimethylamine alane (TMAA) precursor.

4. A method of manufacturing a lift pin for use in semiconductor manufacturing CVD processing, comprising:
forming the lift pin from stainless steel;
oxidizing the lift pin.

5. The method of claim 4, wherein oxidizing the lift pin includes oxidizing the lift pin at a temperature of about 400° C. for a range of time of about 4 to 36 hours.

6. The method of claim 5, wherein oxidizing the lift pin further includes oxidizing the lift pin in one of a group of air, nitrogen, and inert gas.

7. The method of claim 5, wherein oxidizing the lift pin further includes oxidizing the lift pin in substantially a vacuum.

8. The method of claim 7, wherein the vacuum is at a pressure of about 5×10⁻³ Torr.

9. A semiconductor manufacturing CVD processing system, comprising:
a vacuum processing chamber;
a gas supply for supplying a reaction gas into the vacuum processing chamber; and
a pedestal including a plurality of lift pins,
wherein the lift pins are stainless steel oxidized at a predetermined temperature for a predetermined amount of time.

10. The system of claim 9, wherein the predetermined temperature is about 400° C., and the predetermined amount of time is a range of about 4 to 36 hours.

11. The system of claim 10, wherein the reaction gas supplied into the vacuum processing chamber is chosen from methylpyrrolidine alane (MPA) precursor, dimethylethylethylamaine alane (DMEEAA) precursor, dimethylaluminum hydridge (DMAH) precursor, and trimethylamine alane (TMAA) precursor.

12. The system of claim 9, wherein after 2000 wafers undergo a CVD process in the CVD processing system, each of the plurality lift pins do not have aluminum from the reaction gas deposited on a surface of each lift pin.
